(19) United States
(12) Patent Application Publication
(10) Pub. No.: US 2026/0254418 A1
(43) Pub. Date: Aug. 27, 2026

(54) AMPLIFICATION CIRCUIT

(71) Applicant: RichWave Technology Corp., Taipei City (TW)

(72) Inventors: Yi-Hsiang Huang, Taipei City (TW); Ching-Yao Pai, Taipei City (TW)

(73) Assignee: RichWave Technology Corp., Taipei City (TW)

(21) Appl. No.: 19/172,616

(22) Filed: Apr. 7, 2025

(30) Foreign Application Priority Data
Feb. 27, 2025 (TW) 114107287

(51) Int. Cl. H03F 1/26; H03F 3/24

(52) U.S. Cl. CPC H03F 1/26; H03F 3/245; H03F 2200/165; H03F 2200/294; H03F 2200/444; H03F 2200/451; H03F 2203/21112

(57) ABSTRACT

An amplification circuit includes a first signal terminal, a second signal terminal, and a path circuit. The first signal terminal can receive a radio frequency signal. The second signal terminal can output an output signal corresponding to the radio frequency signal. The path circuit includes a radio frequency switch, an electrical overstress circuit, a low-pass filter, a high-pass filter, and an amplifier circuit. The radio frequency switch can selectively receive the radio frequency signal. A first terminal of the radio frequency switch is coupled to the first signal terminal. The low-pass filter and the electrical overstress circuit are coupled in series between a second terminal of the radio frequency switch and a reference voltage terminal, forming a conduction path for discharging electrical charges when an electrical overstress event occurs. The high-pass filter is coupled in parallel with the electrical overstress circuit. The amplifier circuit can amplify the radio frequency signal.

### TECHNICAL FIELD

The present disclosure relates to an amplification circuit, particularly an amplification circuit capable of reducing the impact of electrical overstress events to enhance reliability.

### BACKGROUND

In the field of circuit design, reliability stands as a critical technical parameter. During operation in practical application environments, circuits are susceptible to instantaneous high current events arising from electrical overstress (EOS) phenomena, which may precipitate permanent circuit damage. Consequently, reliability considerations are paramount and must be integrated during the initial circuit design phase. Existing technological approaches for enhancing reliability predominantly require the deployment of larger-sized transistors, thereby substantially increasing design complexity. Furthermore, alternative solutions involving external protection circuits invariably result in excessive layout space consumption. Given the inherent limitations of these conventional methodologies, the technical field demands a more sophisticated approach to address these fundamental reliability challenges.

### SUMMARY

An embodiment provides an amplification circuit, comprising a first signal terminal, a second signal terminal, and a first path circuit. The first signal terminal is used to receive a radio frequency signal. The second signal terminal is used to output an output signal corresponding to the radio frequency signal. The first path circuit comprises a first radio frequency switch, an electrical overstress circuit, a low-pass filter, a high-pass filter, and an amplifier circuit. The first radio frequency switch is used to selectively receive the radio frequency signal, comprising a first terminal and a second terminal. The first terminal of the first radio frequency switch is coupled to the first signal terminal. The low-pass filter is connected in series with the electrical overstress circuit between the second terminal of the first radio frequency switch and a first reference voltage terminal, used to form a low-frequency conduction path to discharge electrical charges through the low-frequency conduction path when an electrical overstress event occurs. The high-pass filter is connected in parallel with the electrical overstress circuit. The amplifier circuit is used to amplify the radio frequency signal, comprising a first terminal coupled to the second terminal of the first radio frequency switch, and a second terminal coupled to the second signal terminal.

### BRIEF DESCRIPTION OF THE DRAWINGS

FIG. 1 illustrates an amplification circuit according to an embodiment.

FIG. 2 to FIG. 5 illustrate amplification circuits according to different embodiments.

FIG. 6 to FIG. 12 illustrate protection circuits coupled to the first radio frequency switch and amplifier circuit according to different embodiments.

FIG. 13 illustrates an amplification circuit according to another embodiment.

FIG. 14 illustrates a radio frequency discharge switch according to an embodiment.

FIG. 15 illustrates a protection circuit according to an embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In the present disclosure, the term “comprising” shall be construed as an open-ended term. By way of illustration, when a circuit is described as comprising specific electronic components, such description shall be interpreted to mean that the circuit may comprise not only the enumerated electronic components but also additional elements not expressly recited herein. Within the present disclosure, when reference is made to one element being coupled to another element, such coupling may constitute direct coupling, or alternatively, may be effectuated through indirect coupling via one or more intervening elements. Within the present disclosure, the term “and/or” is employed to designate the inclusion of one or more items from a plurality of items. By way of illustration, when reference is made to “A, B and/or C,” such reference shall be construed to encompass A, B, C, or any combination thereof. This formulation encompasses all possible permutations, including but not limited to: the selection of a single item (namely, A, B, or C); the selection of any pair of items (namely, A and B, B and C, or A and C); and the selection of all items collectively (namely, A, B, and C). Within the present disclosure, the terms “plurality” or “multiple” denote quantities exceeding one, including but not limited to two, three, or any greater quantity, and may be employed to refer to any integer quantity greater than one.

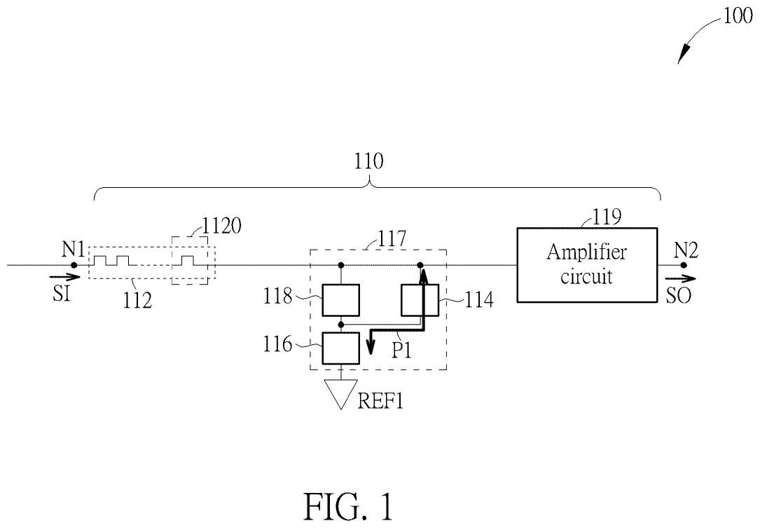

FIG. 1 illustrates an amplification circuit 100 according to an embodiment. The amplification circuit 100 may include a first signal terminal N1, a second signal terminal N2, and a first path circuit 110. The first signal terminal N1 is used to receive a radio frequency signal SI. The second signal terminal N2 is used to output an output signal SO corresponding to the radio frequency signal SI. The first path circuit 110 may include a first radio frequency switch 112, an electrical overstress circuit 114, a low-pass filter 116, a high-pass filter 118, and an amplifier circuit 119. The first path circuit 110 may be coupled to the first signal terminal N1 to receive and process the radio frequency signal SI.

The first radio frequency switch 112 may be used to selectively receive the radio frequency signal SI. The first radio frequency switch 112 may include a first terminal and a second terminal, wherein the first terminal may be coupled to the first signal terminal N1. The low-pass filter 116 and the electrical overstress circuit 114 may be coupled in series between the second terminal of the first radio frequency switch 112 and a first reference voltage terminal REF1, may be used to form a low-frequency conduction path P1, through which electrical charges may be discharged when an electrical overstress event occurs. Therefore, when an electrical overstress event occurs, protection can be effectively provided, thereby improving reliability. The high-pass filter 118 may be coupled in parallel with the electrical overstress circuit 114, that is, the high-pass filter 118 may also be coupled in series with the low-pass filter 116 between the second terminal of the first radio frequency switch 112 and the first reference voltage terminal REF1. The amplifier circuit 119 may be used to amplify the radio frequency signal SI to generate the output signal SO. The amplifier circuit 119 may include a first terminal and a second terminal, wherein the first terminal may be coupled to the second terminal of the first radio frequency switch 112, and the second terminal may be coupled to the second signal terminal N2. The first radio frequency switch 112 may include at least one transistor 1120, or may include a switch string formed by multiple stacked transistors.

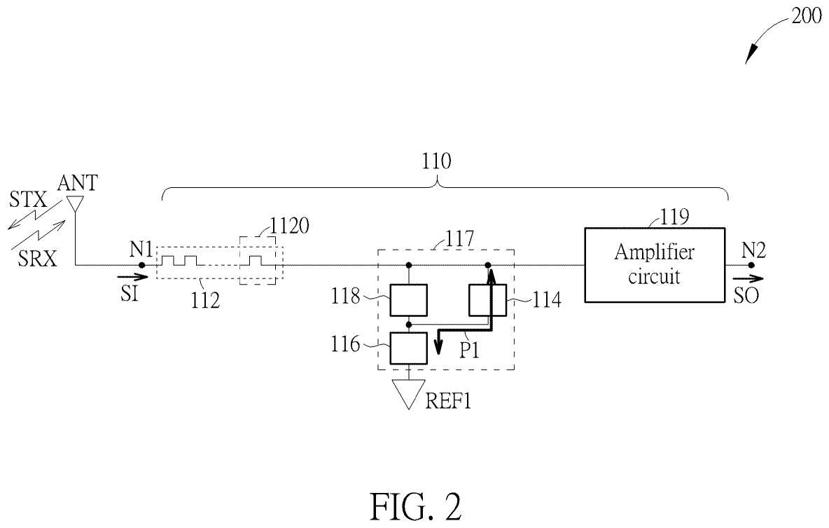

FIG. 2 illustrates an amplification circuit 200 according to another embodiment. The amplification circuit 200 may be similar to the amplification circuit 100, wherein similar aspects may not be repeated herein. The amplification circuit 200 may further include an antenna ANT. The antenna ANT may be coupled to the first signal terminal N1. The antenna ANT may receive an external wireless signal SRX, thereby generating the radio frequency signal SI. In yet another embodiment, the antenna ANT may also generate a wireless signal STX based on the radio frequency signal SI, to wirelessly transmit the wireless signal STX to the exterior, in this embodiment, the transmission direction of the radio frequency signal SI may be opposite to that indicated in FIG. 2. Furthermore, the transmission direction of the output signal SO may also be opposite to that indicated in FIG. 2 (that is, the input/output relationship of the radio frequency signal SI and the output signal SO relative to the amplifier circuit 119 may be reversed). The antenna ANT may include, but is not limited to, a Patch Antenna, a Monopole Antenna, a Dipole Antenna, a Phased Array Antenna, a Loop Antenna, a Slot Antenna, a Microstrip Antenna, and/or a Reflector Antenna. The type of the antenna ANT may be selected based on factors such as system specifications, operating frequency, spatial limitations, gain requirements, and radiation characteristics.

FIG. 1 and FIG. 2 illustrate that the amplifier circuit 119 may be a low noise amplifier (LNA). The low noise amplifier may be used to amplify weak radio frequency signals, and may have an extremely low noise figure while maintaining appropriate signal gain. In wireless communication systems, the low noise amplifier may be positioned at the front-end of the receiver, amplifying the weak radio frequency signals received by the antenna ANT while minimizing the introduction of additional noise, so that subsequent circuits can correctly process the signals.

As shown in FIG. 1 and FIG. 2, the electrical overstress circuit 114, the low-pass filter 116, and the high-pass filter 118 may form a protection circuit 117 to protect other circuits (for example, the amplifier circuit 119). When an electrical overstress event occurs, the protection circuit 117 may be used to discharge current, to prevent current from damaging the circuit, thereby improving reliability. The electrical overstress events described herein may include, but are not limited to, electrostatic discharge (ESD) events, surges caused by power instability, transient surge currents generated by hot-plugging, transient induced currents generated by lightning strikes, transient currents caused by incorrect wiring procedures, and other unexpected events that may damage circuits.

As shown in FIG. 1 and FIG. 2, when an electrical overstress event occurs, such as an electrostatic discharge event, large currents generated by charge movement flowing into or out of the first signal terminal N1 may be directed to the first reference voltage terminal REF1 (for example, ground) through the low-frequency conduction path P1 of the protection circuit 117. When an electrical overstress event occurs, such as an electrostatic discharge event, large currents generated by charge movement originating from the first reference voltage terminal REF1 may be directed to the first signal terminal N1 through the low-frequency conduction path P1 of the protection circuit 117. Therefore, the protection circuit 117 may provide bidirectional discharge paths to reduce damage caused by large currents generated by electrical overstress events flowing through the amplifier circuit 119.

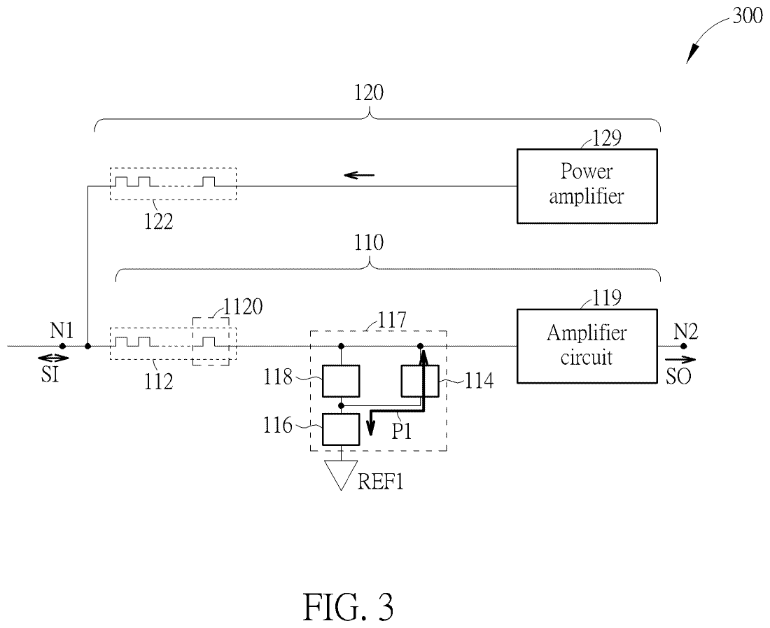

FIG. 3 illustrates an amplification circuit 300 according to another embodiment. Similar aspects between FIG. 3 and FIGS. 1 and 2 may not be repeated herein. The amplification circuit 300 may further include a second path circuit 120. The second path circuit 120 may include a second radio frequency switch 122. In normal operation, either the first radio frequency switch 112 or the second radio frequency switch 122 may be turned on, while the other remains off. For example, the first path circuit 110 may correspond to an amplification mode, while the second path circuit 120 may correspond to a transmission mode or a bypass mode.

FIG. 3 illustrates that if the second path circuit 120 corresponds to a transmission mode, the second path circuit 120 may further include a power amplifier 129, used to amplify signals, to transmit to the first signal terminal N1. The amplified signal may be further transmitted to the antenna through the first signal terminal N1, to perform wireless transmission.

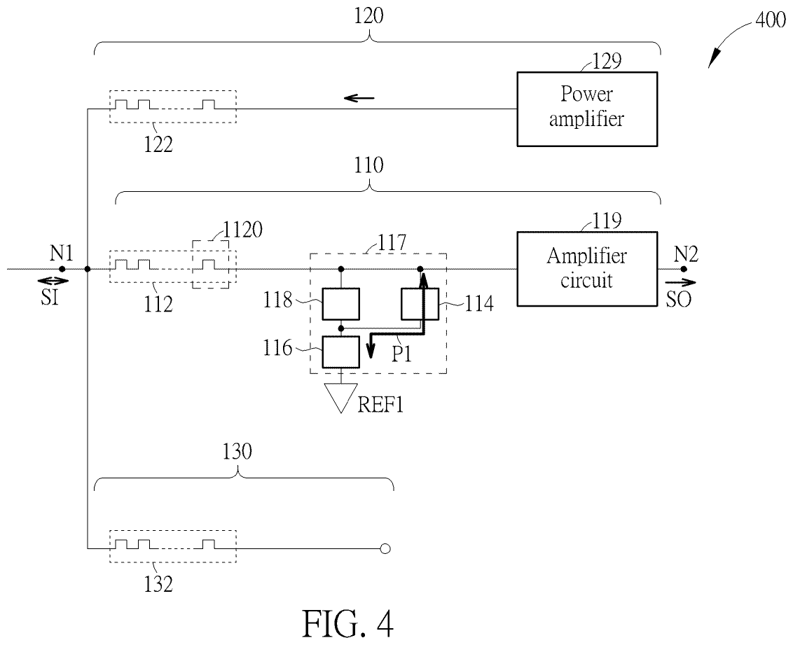

FIG. 4 illustrates an amplification circuit 400 according to another embodiment. Similar aspects between FIG. 4 and FIG. 3 may not be repeated herein. Compared to the amplification circuit 300, the amplification circuit 400 further includes a third path circuit 130. The third path circuit 130 may include a third radio frequency switch 132. In normal operation of the amplification circuit 400, one of the first radio frequency switch 112, the second radio frequency switch 122, and the third radio frequency switch 132 may be turned on, while the other two remain off.

FIG. 4 illustrates various operational modes of the amplification circuit of the present disclosure, as described below. The amplification circuit 400 of FIG. 4 is provided as an example for explanation. Switching between the various modes described below may be performed according to requirements, thereby operating the amplification circuit in one of the various modes described below.

### (Mode-1) Amplification Mode

When operating in the amplification mode, signals may be transmitted through the first path circuit 110, and the radio frequency signal SI received at the first signal terminal N1 may be amplified using the amplifier circuit 119 (for example, a low noise amplifier), thus the amplification mode may be a receiving mode (RX mode). The radio frequency signal SI may be received by an antenna and transmitted to the first signal terminal N1. In the amplification mode, the first radio frequency switch 112 may be turned on, while the second radio frequency switch 122 and the third radio frequency switch 132 may be turned off.

### (Mode-2) Transmission Mode (TX Mode)

When operating in the transmission mode, signals may be transmitted through the second path circuit 120, and the radio frequency signal SI may be transmitted to the antenna for transmission, with the signal being amplified by an amplifier (for example, the power amplifier 129) before being transmitted to the first signal terminal N1. The amplified signal may be further transmitted to the antenna through the first signal terminal N1 for transmission. In the transmission mode, the second radio frequency switch 122 may be turned on, while the first radio frequency switch 112 and the third radio frequency switch 132 may be turned off.

### (Mode-3) Bypass Mode

When operating in the bypass mode, signals may be transmitted through the third path circuit 130. In the bypass mode, signals may be directly transmitted from the first signal terminal N1 to the transceiver circuit. The radio frequency signal SI may be received and transmitted to the first signal terminal N1 by an antenna. In the bypass mode, the third radio frequency switch 132 may be turned on, while the first radio frequency switch 112 and the second radio frequency switch 122 may be turned off.

According to an embodiment, the first path circuit 110 and the third path circuit 130 may be arranged in parallel and connected between the first signal terminal N1 and the transceiver circuit, which means that after the radio frequency signal SI is received by the antenna and transmitted to the first signal terminal N1, the radio frequency signal SI may be selectively transmitted to the transceiver circuit through either the first path circuit 110 or the third path circuit 130.

In the embodiments, each of the first radio frequency switch 112, the second radio frequency switch 122, and the third radio frequency switch 132 may include a transistor. Each of the first radio frequency switch 112, the second radio frequency switch 122, and the third radio frequency switch 132 may be a switch formed by multiple series-connected switches. The aforementioned series-connected switches may be formed through stacked transistors. Using stacked transistors to form switches may achieve higher voltage tolerance, better isolation effects, improved linearity, better control of parasitic capacitance, enhanced high-frequency performance, increased reliability, and easier size adjustment. For example, any of the first radio frequency switch 112, the second radio frequency switch 122, and the third radio frequency switch 132 may include a series of switches formed by stacking at least one transistor 1120.

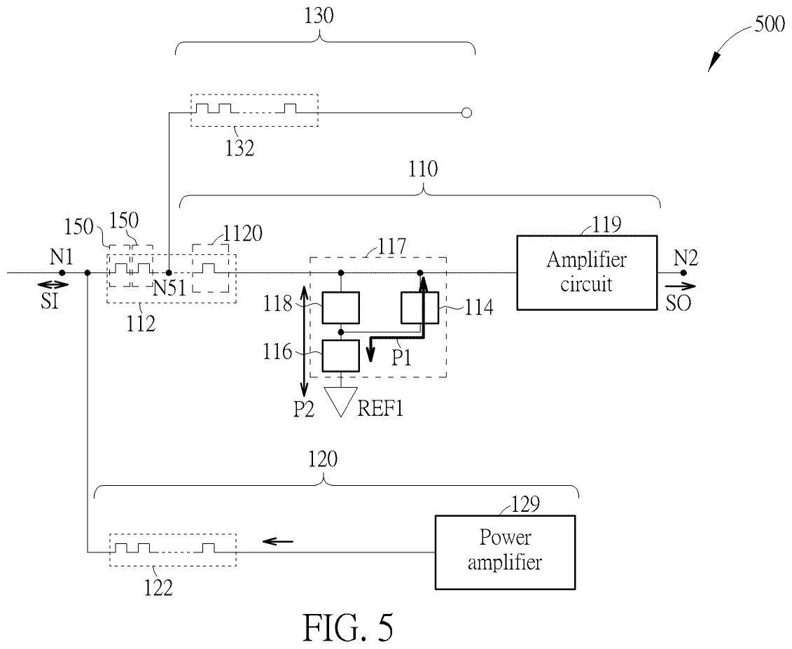

FIG. 5 illustrates an amplification circuit 500 according to another embodiment.

Similar aspects between FIG. 5 and FIG. 4 are not repeated here. As shown in FIG. 5, the first terminals of the first path circuit 110, the second path circuit 120, and the third path circuit 130 may not necessarily be coupled to the same node. In FIG. 5, the third path circuit 130 may be coupled to a node N51. Therefore, the switch 150 may be located in the first path circuit 110, and may be located in the third path circuit 130, as a shared element. In other words, the third path circuit 130 may extend from the node N51 in the first radio frequency switch 112, forming a branch that constitutes a path different from the first path circuit 110. In other words, the radio frequency switch of the first path may be composed of a series of switches formed by stacking at least one transistor 1120, and at least one switch 150 (as shown by the first radio frequency switch 112 in FIG. 5), and the radio frequency switch of the third path may be composed of the third radio frequency switch 132 and the switch 150.

In the embodiments, the low-pass filter 116 may include a low-pass filter circuit formed of active components and/or passive components. The low-pass filter 116 may include an inductor. The inductor of the low-pass filter 116 may have a notch inductance value less than 20 nanohenries (nH). The inductor of the low-pass filter 116 may be an inductance of a bonding wire.

In the embodiments, the high-pass filter 118 may include a high-pass filter circuit formed of active components and/or passive components. In terms of frequency response characteristics, the passband frequency range of the high-pass filter 118 may be higher than the passband frequency range of the low-pass filter 116. The high-pass filter 118 may include a capacitor.

At a specific frequency, the high-pass filter 118 and the low-pass filter 116 may form a specific frequency notch path P2 between the second terminal of the first radio frequency switch 112 and the first reference voltage terminal REF1, to guide the specific frequency signal to the first reference voltage terminal REF1, achieving the purpose of filtering out the specific frequency signal. This specific frequency may be higher than the frequency range of the low-frequency conduction path, may be between 2 gigahertz and 3 gigahertz (2 GHz~3 GHz), for example, may be approximately 2.45 gigahertz. In other words, the low-frequency conduction path P1 and the specific frequency notch path P2 may share the low-pass filter 116, thereby simplifying the design and reducing the area of the amplification circuit.

The signals processed in the amplification mode, the transmission mode, and the bypass mode may have frequencies in the range of 5 gigahertz to 7 gigahertz (5 GHz~7 GHz).

Compared to the signals processed in the amplification mode, the transmission mode, and the bypass mode, the frequency of signals in electrical overstress events (for example, electrostatic discharge events) may be lower frequency signals. For example, the instantaneous frequency of an electrical overstress event is not a fixed value, and it may be between 6 megahertz and 0.1 gigahertz (0.6 MHz~0.1 GHz).

The above frequency values are only examples. By adjusting the structure and component characteristics (for example, capacitance value, inductance value, etc.) of the high-pass filter 118 and the low-pass filter 116, the protection circuit 117 can provide conduction paths at other frequency bands to discharge large currents, thereby providing protection.

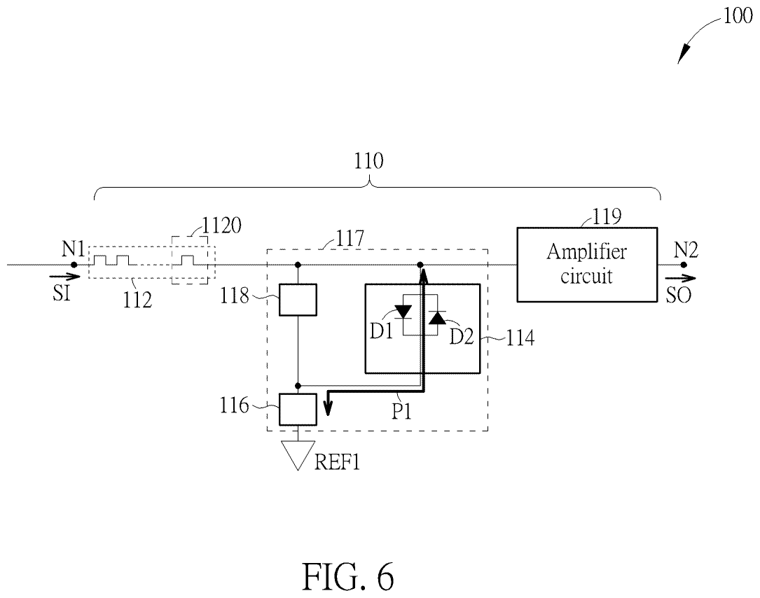

In the following, FIG. 6 to FIG. 10 will further describe various types of the protection circuit 117. FIG. 6 illustrates the protection circuit 117 coupled to the first radio frequency switch 112 and the amplifier circuit 119 according to an embodiment. The electrical overstress circuit 114 may include a first diode D1 and a second diode D2. The first diode D1 may be configured in a forward-biased direction, and the second diode D2 may be configured in a reverse-biased direction. The first diode D1 and the second diode D2 may be connected in parallel (as shown in FIG. 6) between the second terminal of the first radio frequency switch 112 and the low-pass filter 116. When a large current generated by an electrical overstress event comes from the first signal terminal N1, the large current can be discharged to the first reference voltage terminal REF1 (for example, ground) through the first diode D1. When a large current generated by an electrical overstress event comes from the first reference voltage terminal REF1, the large current can be discharged to the first signal terminal N1 through the second diode D2.

The first diode D1 and the second diode D2 may form a clamp circuit structure. This clamp circuit can provide bidirectional protection, where the diodes may conduct when the input terminal is subjected to low-frequency noise or transient interference exceeding the normal operating voltage range. Specifically, the forward conduction voltage of the diodes may prevent circuit elements from being damaged. This protection structure is applicable to input/output interface circuits in analog signal processing circuits. Its structure is simple, with fast response speed, and high reliability. Since the protection circuit 117 already provides protection, the architecture disclosed herein may not require other clamp circuits besides the protection circuit 117 to handle large currents from electrical overstress events.

In the protection circuit 117 described in this document, the electrical overstress circuit 114 and the low-pass filter 116 (for example, but not limited to, an inductor) in the low-frequency domain, may form a clamp circuit, handling unexpected current changes, to provide protection, reducing damage from electrical overstress events.

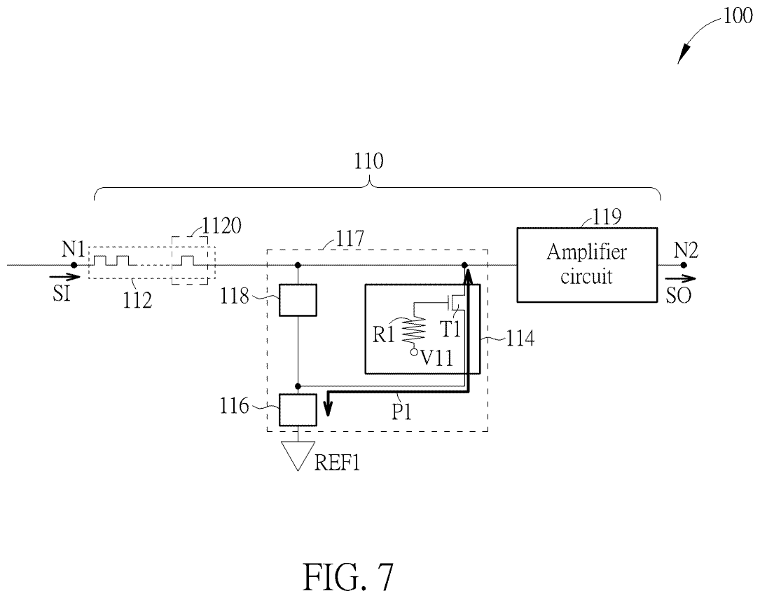

FIG. 7 illustrates the protection circuit 117 coupled to the first radio frequency switch 112 and the amplifier circuit 119 according to another embodiment. The electrical overstress circuit 114 may include a transistor T1 and a first resistor R1. The transistor T1 may include a first terminal, a second terminal, and a control terminal. The first terminal of the transistor T1 may be coupled to the second terminal of the first radio frequency switch 112, the second terminal of the transistor T1 may be coupled to the first terminal of the low-pass filter 116, and the control terminal of the transistor T1 may be coupled to one terminal of the first resistor R1. The other terminal of the first resistor R1 may receive a voltage V11. The voltage V11 may be a predetermined voltage to keep the transistor T1 in an OFF state when an electrical overstress event occurs. Taking the transistor T1 as an N-type transistor as an example, the voltage V11 may be a negative voltage or a zero voltage. The control terminal of the transistor T1 may be a gate terminal. In this document, if the transistor T1 is a metal-oxide-semiconductor transistor, it may be a grounded-gate N-type metal-oxide-semiconductor transistor (grounded-gate NMOS, GGNMOS), or a grounded-gate N-type metal-oxide-semiconductor transistor with resistor (grounded-gate NMOS with resistor, GRNMOS).

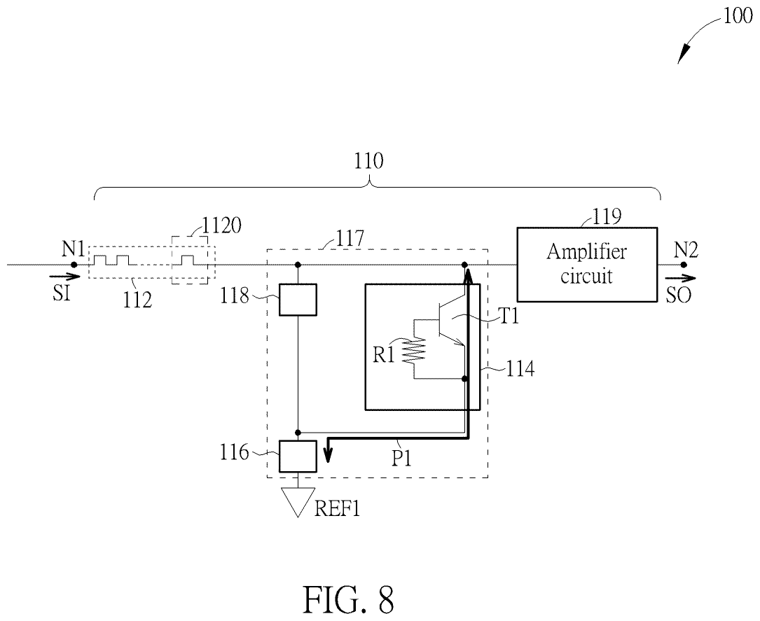

FIG. 8 illustrates the protection circuit 117 coupled to the first radio frequency switch 112 and the amplifier circuit 119 according to another embodiment. In FIG. 8, one terminal of the first resistor R1 may be coupled to the control terminal of the transistor T1. Similar aspects between FIG. 8 and FIG. 7 are not repeated. Different from FIG. 7, in FIG. 8, the other terminal of the first resistor R1 is coupled to the second terminal of the transistor T1. The transistor T1 may be a bipolar junction transistor (BJT), where its first terminal, second terminal, and control terminal may be a collector terminal, an emitter terminal, and a base terminal, respectively.

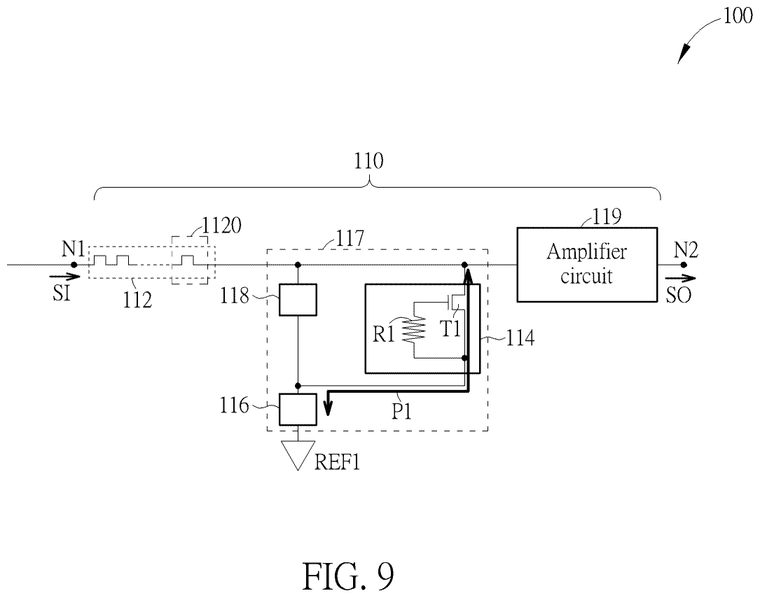

FIG. 9 illustrates the protection circuit 117 coupled to the first radio frequency switch 112 and the amplifier circuit 119 according to another embodiment. In FIG. 9, one terminal of the first resistor R1 is coupled to the control terminal of the transistor T1. Similar aspects between FIG. 9 and FIG. 7 are not repeated, and the difference between FIG. 9 and FIG. 7 is that the other terminal of the first resistor R1 is coupled to the second terminal of the transistor T1. The transistor T1 may be a field effect transistor, where its first terminal, second terminal, and control terminal may be a drain terminal, a source terminal, and a gate terminal, respectively.

In FIG. 7 to FIG. 9, the transistor T1 may establish a low-frequency conduction path P1 through coupling effects or breakdown effects. The low-frequency conduction path P1 may be used to divert abnormally large currents, thereby realizing a protection mechanism.

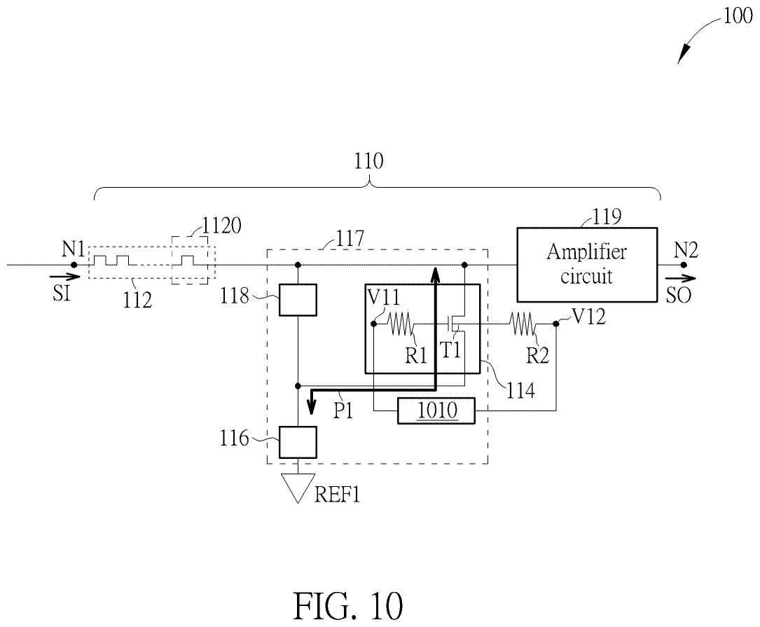

FIG. 10 illustrates the protection circuit 117 coupled to the first radio frequency switch 112 and the amplifier circuit 119 according to another embodiment. Similar aspects between FIG. 10 and FIG. 7 are not repeated. As shown in FIG. 10, the electrical overstress circuit 114 may further include a second resistor R2. One terminal of the second resistor R2 may be coupled to the body terminal of the transistor T1, and the other terminal of the second resistor R2 may receive voltage V12. The voltage V12 may be a predetermined voltage to keep the transistor T1 in an OFF state when an electrical overstress event occurs. Taking the transistor T1 as an N-type transistor as an example, the voltage V12 may be a negative voltage or zero voltage. Depending on requirements, the second resistor R2 may be omitted. In FIG. 10, through coupling effects, the transistor T1 may be made conductive, to establish a low-frequency conduction path P1, to divert abnormally large currents, thereby realizing a protection mechanism.

In FIG. 7 and FIG. 10, the first resistor R1 and/or the second resistor R2 may be coupled to a bias circuit 1010. The bias circuit 1010 may provide a control bias to provide voltage V11 to the first resistor R1. The bias circuit 1010 may also provide a substrate bias to provide voltage V12 to the second resistor R2. The bias circuit 1010 may include a ground terminal, a negative voltage generator (for example, a charge pump), a transformer, a node with an appropriate voltage, an appropriate conductive layer, or other suitable circuits, so that when an electrical overstress event occurs, the transistor T1 may be made conductive through coupling effects or broken down through breakdown effects, establishing a low-frequency conduction path P1. The voltage V11 and the voltage V12 in FIG. 10 may be the same or different.

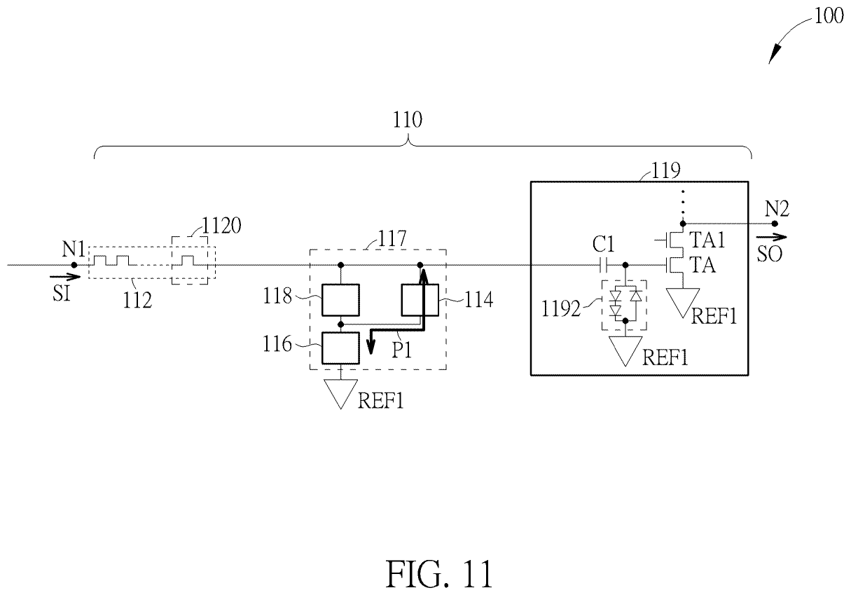

FIG. 11 illustrates the protection circuit 117 coupled to the first radio frequency switch 112 and the amplifier circuit 119 according to another embodiment. The protection circuit 117 in FIG. 11 may be as shown in any of the above figures. The amplifier circuit 119 in FIG. 11 may include an amplifying transistor TA. A control terminal of the amplifying transistor TA may be coupled to the second terminal of the first radio frequency switch 112, a second terminal of the amplifying transistor TA may be coupled to the first reference voltage terminal REF1, and a first terminal of the amplifying transistor TA may be coupled to the second signal terminal N2.

In FIG. 11, the amplifier circuit 119 may further include an amplifying transistor TA1, where the amplifying transistor TA1 and the amplifying transistor TA may be coupled in a stacked manner, and the first terminal of the amplifying transistor TA may be coupled to the second signal terminal N2 through the amplifying transistor TA1. However, FIG. 11 is only an example. The amplifying transistor TA1 may be optionally omitted, and the first terminal of the amplifying transistor TA may be directly coupled to the second signal terminal N2, which also falls within the scope of embodiments.

In FIG. 11, the amplifier circuit 119 may further include an input capacitor C1. The control terminal of the amplifying transistor TA may be coupled to the second terminal of the first radio frequency switch 112 through the input capacitor C1. The amplifier circuit 119 may further include a clamp circuit 1192, where the clamp circuit 1192 may be connected between the control terminal of the amplifying transistor TA and the first reference voltage terminal REF1. When the input signal or noise exceeds the predetermined range, the clamp circuit 1192 may limit the voltage swing, preventing the amplifier circuit 119 from being damaged by excessive stress. This protection mechanism can ensure the operation of the amplifier circuit 119 and extend the lifetime of the amplifier circuit 119.

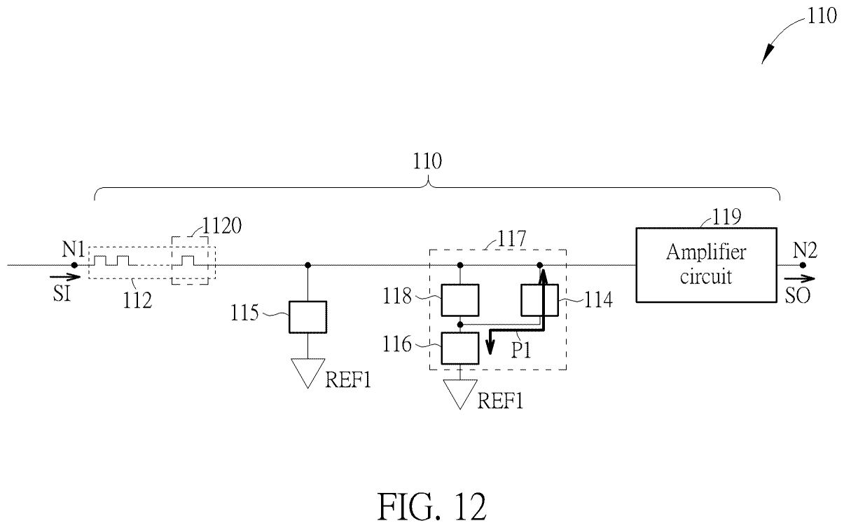

FIG. 12 illustrates the first path circuit 110 in another embodiment. The similarities between FIG. 12 and the aforementioned embodiment will not be reiterated. As shown in FIG. 12, the first path circuit 110 may further include a radio frequency discharge switch 115. The radio frequency discharge switch 115 may be connected between the second terminal of the first radio frequency switch 112 and the first reference voltage terminal REF1. The radio frequency discharge switch 115 may operate as a shunt switch, used to discharge unintended radio frequency signals to a predetermined terminal, such as a ground terminal, thereby improving the isolation between multiple paths. When the first radio frequency switch 112 is turned on, the radio frequency discharge switch 115 may be turned off. When the first radio frequency switch 112 is turned off, the radio frequency discharge switch 115 may be turned on.

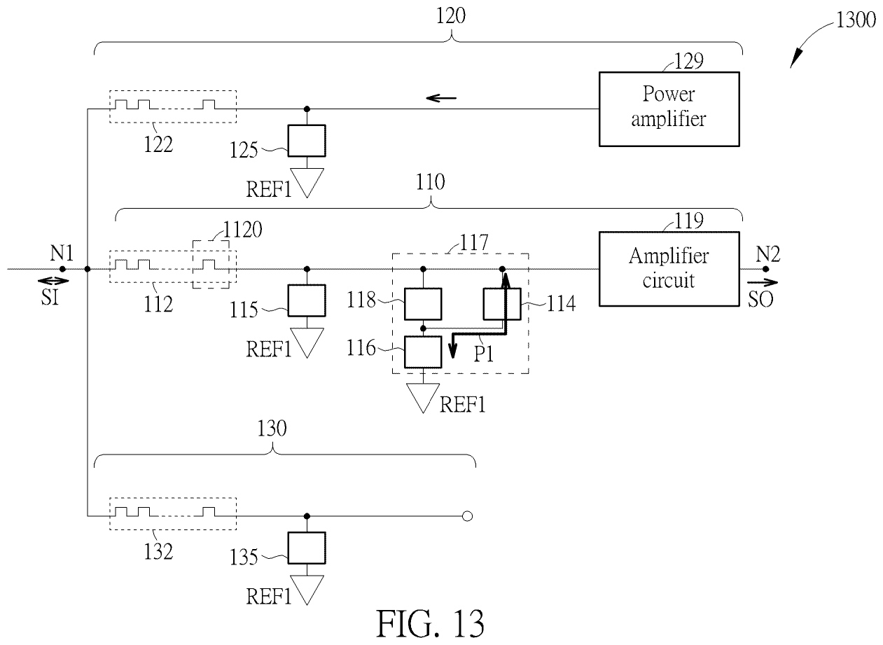

FIG. 13 illustrates an amplification circuit 1300 according to another embodiment. The similarities between the amplification circuit 1300 and the amplification circuit 400 are not reiterated. In the amplification circuit 1300, the first path circuit 110 may include a radio frequency discharge switch 115 connected between the second terminal of the first radio frequency switch 112 and the first reference voltage terminal REF1. The second path circuit 120 may include a radio frequency discharge switch 125 connected between the second terminal of the second radio frequency switch 122 and the first reference voltage terminal REF1. The third path circuit 130 may include a radio frequency discharge switch 135 connected between the second terminal of the third radio frequency switch 132 and the first reference voltage terminal REF1. The radio frequency discharge switches 115, 125, and 135 illustrated in FIG. 13 may be selectively arranged, for example, one or two of them may be omitted as needed.

When operating in an amplification mode, the signal can be transmitted through the first path circuit 110. The first radio frequency switch 112 may be turned on, the radio frequency discharge switch 115 may be turned off, the second radio frequency switch 122 and the third radio frequency switch 132 may be turned off, and the radio frequency discharge switches 125 and 135 may be turned on.

When operating in a transmission mode, the signal can be transmitted through the second path circuit 120. The second radio frequency switch 122 may be turned on, the radio frequency discharge switch 125 may be turned off, the first radio frequency switch 112 and the third radio frequency switch 132 may be turned off, and the radio frequency discharge switches 115 and 135 may be turned on.

When operating in a bypass mode, the signal can be transmitted through the third path circuit 130. The third radio frequency switch 132 may be turned on, the radio frequency discharge switch 135 may be turned off, the first radio frequency switch 112 and the second radio frequency switch 122 may be turned off, and the radio frequency discharge switches 115 and 125 may be turned on.

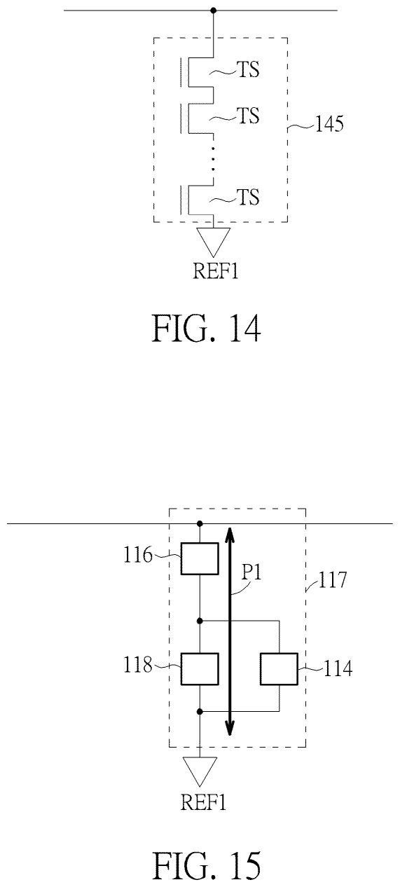

FIG. 14 illustrates a radio frequency discharge switch 145 according to an embodiment.

The radio frequency discharge switch 145 may represent the circuit architecture of the radio frequency discharge switches 115, 125, and 135. As shown in FIG. 14, the radio frequency discharge switch 145 may include a discharge transistor TS. A first terminal of the discharge transistor TS may be coupled to the second terminal of a radio frequency switch (e.g., one of the radio frequency switches 112, 122, or 132), and a second terminal of the discharge transistor TS may be coupled to the first reference voltage terminal REF1. As illustrated in FIG. 14, the radio frequency discharge switch 145 may be formed using multiple series-connected switches, which may include stacked transistors to improve circuit performance. The stacked transistors in the radio frequency discharge switch 145 may be synchronously turned on or off.

FIG. 15 illustrates the protection circuit 117 according to another embodiment. The configuration of the components in the protection circuit 117 of FIG. 15 may differ from the descriptions above. As shown in FIG. 15, in the protection circuit 117, the low-pass filter 116 may be coupled to the second terminal of a radio frequency switch (e.g., one of the radio frequency switches 112, 122, or 132). The high-pass filter 118 may be coupled between the low-pass filter 116 and the first reference voltage terminal REF1. The electrical overstress circuit 114 may be coupled between the low-pass filter 116 and the first reference voltage terminal REF1. The high-pass filter 118 and the electrical overstress circuit 114 may be coupled in parallel between the low-pass filter 116 and the first reference voltage terminal REF1. In other words, compared to the configurations in FIG. 1 to FIG. 13, in FIG. 15, the low-pass filter 116 may be adjusted and moved to a position between the radio frequency switch (e.g., one of the radio frequency switches 112, 122, or 132) and the electrical overstress circuit 114. The electrical overstress circuit 114 in FIG. 15 may be used and correspond to one of those shown in FIG. 6 to FIG. 10.

In summary, in the amplification circuit provided by the embodiment, the low-frequency conduction path P1 of the protection circuit 117 can offer a bidirectional protection mechanism to discharge unintended high current during electrical overstress events (e.g., electrostatic discharge events), thereby reducing damage. Furthermore, since the low-frequency conduction path P1 and the specific frequency notch path P2 can share the low-pass filter 116, the design can be simplified, and the size of the amplification circuit can be reduced. Additionally, as it is possible to discharge high current during electrical overstress events without using the radio frequency discharge switches (e.g., the radio frequency discharge switches 115, 125, and 135 in FIG. 13), the transistor size of the radio frequency discharge switches can be effectively reduced, avoiding issues such as excessive circuit size, limited design space, and poor characteristics of parasitic capacitance. Moreover, by utilizing the protection circuit 117, the need for externally installing protection circuits is reduced. For instance, protection circuits may not need to be installed at the antenna location, thus preventing excessive layout space occupation. The response speed of the protection circuit 117 is sufficiently fast, enabling rapid discharge of high current during electrical overstress events to minimize damage. Therefore, the solutions provided by embodiments enhance circuit reliability, improve circuit characteristics, reduce design complexity, and optimize circuit layout.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification circuit, comprising:
a first signal terminal, configured to receive a radio frequency signal;
a second signal terminal, configured to output an output signal corresponding to the radio frequency signal; and
a first path circuit, comprising:
a first radio frequency switch, configured to selectively receive the radio frequency signal, and comprising a first terminal coupled to the first signal terminal, and a second terminal;
an electrical overstress circuit;
a low-pass filter, coupled in series with the electrical overstress circuit between the second terminal of the first radio frequency switch and a first reference voltage terminal, and configured to form a low-frequency conduction path to discharge electrical charges through the low-frequency conduction path when an electrical overstress event occurs;
a high-pass filter, coupled in parallel with the electrical overstress circuit; and
an amplifier circuit, configured to amplify the radio frequency signal, and comprising a first terminal coupled to the second terminal of the first radio frequency switch, and a second terminal coupled to the second signal terminal.

2. The amplification circuit of claim 1, further comprising an antenna coupled to the first signal terminal.

3. The amplification circuit of claim 1, wherein the amplifier circuit is a low noise amplifier.

4. The amplification circuit of claim 3, further comprising a second path circuit, wherein the second path circuit comprises a second radio frequency switch, and in a normal operation, the first radio frequency switch or the second radio frequency switch is turned on.

5. The amplification circuit of claim 4, wherein the second path circuit further comprises a power amplifier.

6. The amplification circuit of claim 4, wherein the second path circuit further comprises a radio frequency discharge switch, and the radio frequency discharge switch is coupled between the second terminal of the second radio frequency switch and the first reference voltage terminal.

7. The amplification circuit of claim 3, further comprising a second path circuit and a third path circuit, wherein the second path circuit comprises a second radio frequency switch, the third path circuit comprises a third radio frequency switch, and in a normal operation, the first radio frequency switch, the second radio frequency switch, or the third radio frequency switch is turned on.

8. The amplification circuit of claim 1, wherein the low-pass filter comprises an inductor.

9. The amplification circuit of claim 1, wherein the high-pass filter and the low-pass filter form a conduction path between the second terminal of the first radio frequency switch and a first reference voltage terminal at a specific frequency.

10. The amplification circuit of claim 1, wherein the high-pass filter comprises a capacitor.

11. The amplification circuit of claim 1, wherein the electrical overstress circuit comprises a first diode and a second diode, the first diode is configured in a forward-biased direction, the second diode is configured in a reverse-biased direction, the first diode and the second diode are coupled in parallel between the second terminal of the first radio frequency switch and the low-pass filter.

12. The amplification circuit of claim 1, wherein the electrical overstress circuit comprises a transistor and a first resistor, and the transistor comprises a first terminal coupled to the second terminal of the first radio frequency switch, a second terminal coupled to a first terminal of the low-pass filter, and a control terminal coupled to a first terminal of the first resistor.

13. The amplification circuit of claim 12, wherein a second terminal of the first resistor is coupled to the second terminal of the transistor, and the transistor is a bipolar transistor or a field effect transistor.

14. The amplification circuit of claim 12, wherein the electrical overstress circuit comprises a second resistor, and the transistor is a field effect transistor, and a first terminal of the second resistor is coupled to a body of the field effect transistor.

15. The amplification circuit of claim 14, wherein a second terminal of the first resistor and a second terminal of the second resistor are coupled to a bias circuit, the bias circuit provides a control bias voltage to the second terminal of the first resistor, and the bias circuit provides a substrate bias voltage to the second terminal of the second resistor.

16. The amplification circuit of claim 1, wherein the amplifier circuit comprises an amplifying transistor, a control terminal of the amplifying transistor is coupled to the second terminal of the first radio frequency switch, a second terminal of the amplifying transistor is coupled to the first reference voltage terminal, and a first terminal of the amplifying transistor is coupled to the second signal terminal.

17. The amplification circuit of claim 16, wherein the amplifier circuit further comprises an input capacitor, and the control terminal of the amplifying transistor is coupled to the second terminal of the first radio frequency switch through the input capacitor.

18. The amplification circuit of claim 16, wherein the amplifier circuit further comprises a clamping circuit, and the clamping circuit is coupled between the control terminal of the amplifying transistor and the first reference voltage terminal.

19. The amplification circuit of claim 1, wherein the electrical overstress circuit and the low-pass filter form a clamping circuit at a low frequency.

20. The amplification circuit of claim 1, wherein the first path circuit further comprises a radio frequency discharge switch, and the radio frequency discharge switch is coupled between the second terminal of the first radio frequency switch and the first reference voltage terminal.
